(19) United States
(12) Patent Application Publication
(10) Pub. No.: US 2021/0166899 A1
(43) Pub. Date: Jun. 3, 2021

(54) THERMAL SWITCH, COOLING DEVICE, AND DISPLAY DEVICE

(71) Applicant: SHARP KABUSHIKI KAISHA, Sakai City (JP)

(72) Inventors: YASUHIRO HASEBA, Sakai City (JP); KIYOSHI MINOURA, Sakai City (JP)

(21) Appl. No.: 17/105,285

(22) Filed: Nov. 25, 2020

(30) Foreign Application Priority Data
Nov. 29, 2019 (JP) 2019-216971

(51) Int. Cl. H01H 37/32; H05K 7/20

(52) U.S. Cl. CPC H01H 37/32; H05K 5/0017; H05K 7/20963

(57) ABSTRACT

A thermal switch includes: a first electrode; a second electrode opposite the first electrode; and a liquid crystal layer between the first electrode and the second electrode, the liquid crystal layer containing liquid crystal molecules that are at least either in the Williams domain mode or in the dynamic scattering mode when a voltage is applied between the first electrode and the second electrode.

### TECHNICAL FIELD

The present disclosure relates to thermal switches, cooling devices, and display devices.

### BACKGROUND ART

Non-patent Literature 1 describes that the thickness-wise thermal conductivity of a liquid crystal layer containing liquid crystal molecules changes with the alignment of the liquid crystal molecules. Non-patent Literature 1 further describes that this is an influence of the length-width ratio and the intermolecular distance of the liquid crystal molecules.

Applications of such materials that the thickness-wise thermal conductivity of the liquid crystal layer changes with the alignment of the liquid crystal molecules may be found in the field of, for example, thermal switches.

Throughout the present specification, a “thermal switch” refers to a switch the thermal conductivity of which changes with a change in applied voltage and/or the frequency thereof.

### CITATION LIST

### Non-Patent Literature

Non-patent Literature 1: M. Marinelli, F. Mercuri, U. Zammit, and F. Scudieri, “Thermal conductivity and thermal diffusivity of the cyanobiphenyl (nCB) homologous series)”, Phys. Rev. E 58, 5860-5866 (1 Nov. 1998)

Non-patent. Literature 2: SASAKI Ryoma, SHIINO Ryosuke, HAYASHI Yoshihiro, and KAWAUCHI Susumu, “Molecular dynamics study of the anisotropy of the thermal conductivity in cyanobiphenyl liquid crystals,” Proceedings of Japanese Liquid Crystal Society Annual meeting, PA03, 2019

### SUMMARY

### Problems to be Solved by the Disclosure

FIGS. 13 and 14 are illustrations of issues of conventional thermal switches in which the liquid crystal molecules are aligned horizontally when the thermal switch is off and vertically when the thermal switch is on.

FIG. 13 shows a thermal switch 100 being off, or more specifically, 5CB liquid crystal molecules 103 being horizontally aligned with no voltage applied between an upper electrode 101 and a lower electrode 102. When the 5CB liquid crystal molecules 103 are thus aligned, the liquid crystal layer containing the 5CB liquid crystal molecules 103 exhibits a thermal conductivity of approximately 0.12 W/mK at 25° C.

FIG. 14 shows the thermal switch 100 being on, or more specifically, the 5CB liquid crystal molecules 103 being vertically aligned with a voltage applied between the upper electrode 101 and the lower electrode 102. When the 5CB liquid crystal molecules 103 are thus aligned, the liquid crystal layer containing the 5CB liquid crystal molecules 103 exhibits a thermal conductivity of approximately 0.23 W/mK at 25° C.

As described in the foregoing, the conventional thermal switch in which the liquid crystal molecules are aligned horizontally when the thermal switch is off and vertically when the thermal switch is on, if turned on/off to change the alignment of the liquid crystal molecules, has a thermal conductivity on/off ratio of no more than about 2 to 3.

Conventional thermal switches, the thermal conductivity of which has an on/off ratio of no more than about 2 to 3, have insufficient performance because the thermal switch preferably has a thermal conductivity on/off ratio of at least about 10 to 100.

Accordingly, taking into consideration, for example, the factors that can contribute to heat transfer processes in a liquid crystal layer described in Non-patent Literature 2, the inventors have diligently worked to find that conventional thermal switches in which the liquid crystal molecules are aligned horizontally when the thermal switch is off and vertically when the thermal switch is on have a low thermal conductivity on/off ratio because these factors have insufficient differences in contribution thereof to the thermal conductivity between when the liquid crystal molecules are vertically aligned and when the liquid crystal molecules are horizontally aligned.

The present disclosure has been made in view of these issues and findings and has an object to provide a thermal switch with a sufficiently high thermal conductivity on/off ratio, a cooling device with high cooling efficiency and high cooling capability, and a display device with good properties or properties that are less likely to be degraded at high temperature.

### Solution to the Problems

To address the issues, the disclosure, in an aspect thereof, is directed to a thermal switch including: a first electrode; a second electrode opposite the first electrode; and a liquid crystal layer between the first electrode and the second electrode, the liquid crystal layer containing liquid crystal molecules that are at least either in Williams domain mode or in dynamic scattering mode when a voltage is applied between the first electrode and the second electrode.

To address the issues, the disclosure, in another aspect thereof, is directed to a cooling device including: at least one electrocaloric device including: a third electrode; a fourth electrode opposite the third electrode; and an electrocaloric material between the third electrode and the fourth electrode; and at least one thermal switch.

To address the issues, the disclosure, in a further aspect thereof, is directed to a display device including: the cooling device; and a display panel.

### Advantageous Effects of the Disclosure

The disclosure, in an aspect thereof, provides a thermal switch with a sufficiently high thermal conductivity on/off ratio, a cooling device with high cooling efficiency and high cooling capability; and a display device with good properties or properties that are less likely to be degraded at high temperature.

### BRIEF DESCRIPTION OF DRAWINGS

FIG. 1 is a diagram of a thermal switch in accordance with Embodiment 1 in the OFF state.

FIG. 2 is a diagram representing characteristics of liquid crystal molecules in a liquid crystal layer in the thermal switch in accordance with Embodiment 1 when the thermal switch is on.

FIG. 3 is a diagram of the thermal switch in accordance with Embodiment 1 in the ON state, the liquid crystal molecules in the liquid crystal layer therein being in the Williams domain mode.

FIG. 4 is a diagram of the thermal switch in accordance with Embodiment 1 in the ON state, the liquid crystal molecules in the liquid crystal layer therein being in the dynamic scattering mode.

FIG. 5 is a diagram of a cooling device in accordance with Embodiment 2 in a first state.

FIG. 6 is a diagram of the cooling device in accordance with Embodiment 2 in a second state.

FIG. 7 is a table of examples of electrocaloric materials used in the cooling device in accordance with Embodiment 2.

FIG. 8 is a diagram of a cooling device in accordance with Embodiment 3 in a first state.

FIG. 9 is a diagram of the cooling device in accordance with Embodiment 3 in a second state,

FIG. 10 is a diagram of the cooling device in accordance with Embodiment 3 in a third state.

FIG. 11 is a schematic diagram of a structure of a display device including the cooling device in accordance with Embodiment 2 shown in FIGS. 5 and 6.

FIG. 12 is a schematic diagram of a structure of a display device including the cooling device in accordance with Embodiment 3 shown in FIGS. 8, 9, and 10.

FIG. 13 is an illustration of issues of a thermal switch containing a conventional liquid crystal material.

FIG. 14 is another illustration of issues of a thermal switch containing a conventional liquid crystal material.

### DESCRIPTION OF EMBODIMENTS

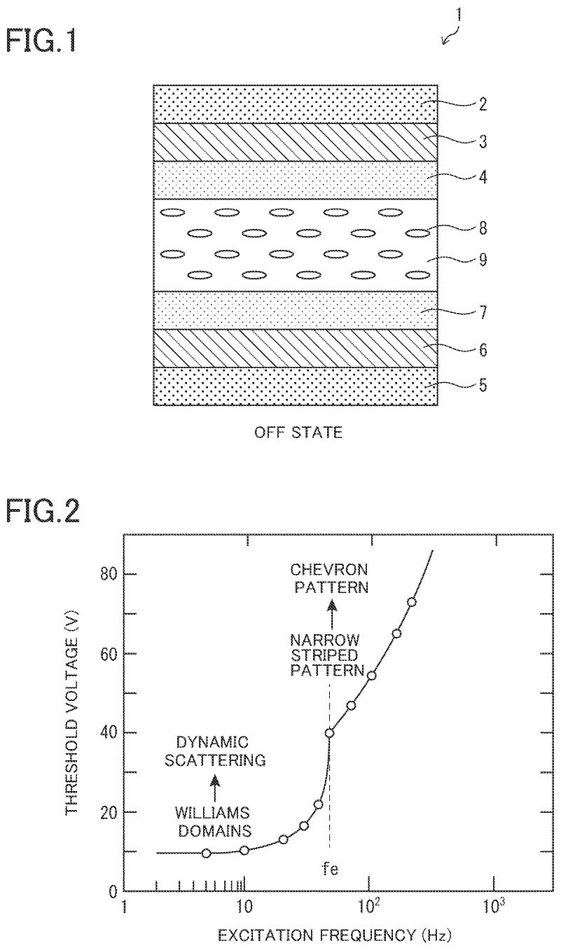

The following will describe embodiments of the present disclosure with reference to FIGS. 1 to 12. Throughout the following, members of an embodiment that have the same arrangement and function as members of a previous embodiment are indicated by the same reference numerals and description thereof may be omitted for convenience of description.

FIG. 1 is a diagram of a thermal switch 1 in accordance with Embodiment 1 in the OFF state.

Referring to FIG. 1, the thermal switch 1 includes a first electrode 3, a second electrode 6 opposite the first electrode 3, and a liquid crystal layer 9 between the first electrode 3 and the second electrode 6. The liquid crystal layer 9 contains liquid crystal molecules 8.

Referring to FIG. 1, the first electrode 3 is provided on a surface (lower surface) of a substrate 2. There is provided an alignment film 4 on the first electrode 3, facing the liquid crystal layer 9 containing the liquid crystal molecules 8. The second electrode 6 is provided on a surface (upper surface) of a substrate 5. There is provided an alignment film 7 on the second electrode 6, facing the liquid crystal layer 9 containing the liquid crystal molecules 8. The upper substrate including the substrate 2, the first electrode 3, and the alignment film 4 is attached, by a sealing member (not shown), to the lower substrate including the substrate 5, the second electrode 6, and the alignment film 7. The liquid crystal layer 9 is enclosed by the sealing member.

Referring to FIG. 1, the liquid crystal molecules 8 in the liquid crystal layer 9 in the thermal switch 1 are oriented homogeneously under no voltage between the first electrode 3 and the second electrode 6, in other words, when the thermal switch 1 is off. In the present embodiment, the liquid crystal molecules 8 are oriented homogeneously when the thermal switch 1 is off in order to achieve a high thermal conductivity on/off ratio by lowering the thermal conductivity in the OFF state. This is however not the only possible implementation of the disclosure. For example, if the thermal conductivity is increased sufficiently in the ON state to achieve a high thermal conductivity on/off ratio, the liquid crystal molecules 8 are not necessarily oriented homogeneously when the thermal switch 1 is off.

FIG. 2 is a diagram representing characteristics of the liquid crystal molecules 8 in the liquid crystal layer 9 in the thermal switch 1 in accordance with Embodiment 1 when the thermal switch 1 is on.

The liquid crystal molecules 8 in the liquid crystal layer 9 in the thermal switch 1 is either in the Williams domain mode or in the dynamic scattering mode when the thermal switch 1 is on, in other words, when an AC voltage is applied between the first electrode 3 and the second electrode 6 in the thermal switch 1, the AC voltage having such a combination of a prescribed frequency (excitation frequency) and a voltage (effective voltage Vrms) greater than or equal to a prescribed threshold voltage (V) shown in FIG. 2 that the liquid crystal molecules are either in the Williams domain mode or in the dynamic scattering mode shown in FIG. 2. In the present embodiment, the Williams domain mode or the dynamic scattering mode is achieved in the liquid crystal. molecules 8 in the liquid crystal layer 9 in the thermal switch 1 by applying an AC voltage as an example. This is however not the only possible implementation of the disclosure. Alternatively, for example, a DC voltage may be applied between the first electrode 3 and the second electrode 6 while controlling the first electrode 3 and the second electrode 6 to achieve the Williams domain mode or the dynamic scattering mode in the liquid crystal molecules 8 in the liquid crystal layer 9 in the thermal switch 1.

The liquid crystal molecules 8 in the liquid crystal layer 9 in the thermal switch 1 convect in a significant manner both during the process of achieving the Williams domain mode or the dynamic scattering mode in the liquid crystal molecules 8 and while maintaining the Williams domain mode or the dynamic scattering mode. As a result, the thermal conductivity increases significantly when the thermal switch 1 is on. In other words, when the thermal switch 1 is off, the liquid crystal molecules 8 so barely convect that the thermal conductivity is low. When the thermal switch 1 is on, in particular, when the liquid crystal molecules 8 are in the Williams domain mode or the dynamic scattering mode, the liquid crystal molecules 8 move at increased speed, and hence the thermal conductivity increases.

The thermal switch 1, when on, exhibits a sufficiently high thermal conductivity because of the convection of the liquid crystal molecules 8 as described in the foregoing. The thermal switch 1 thus exhibits a thermal conductivity on/off ratio of 10 to 100, depending on the OFF-state thermal conductivity of the thermal switch 1.

The threshold voltage (V) in FIG. 2 is the effective voltage Vrms of the AC voltage applied between the first electrode 3 and the second electrode 6 when the liquid crystal layer 9 containing the liquid crystal molecules 8 has a thickness of 10 μm.

The liquid crystal molecules become electrohydrodynamically unstable at excitation frequencies (Hz) lower than fe in FIG. 2 and dielectrically unstable at excitation frequencies higher than fe in FIG. 2.

As shown in FIG. 2, the Williams domain mode resides in the region where the excitation frequency (Hz) causes electrohydrodynamic instability and is achieved under an applied voltage (V) that is higher than a prescribed threshold voltage. The dynamic scattering mode resides in the region where the excitation frequency (Hz) causes electrohydrodynamic instability and is achieved under an applied voltage (V) that is higher than the voltage at which the Williams domain mode is achieved.

Meanwhile, as shown in FIG. 2, the narrow striped pattern mode resides in the region where the excitation frequency (Hz) causes dielectric instability and is achieved under an applied voltage (V) that is 40 V or greater. The chevron pattern mode resides in the region where the excitation frequency (Hz) causes dielectric instability and is achieved under an applied voltage (V) that is higher than the voltage at which the narrow striped pattern mode is achieved.

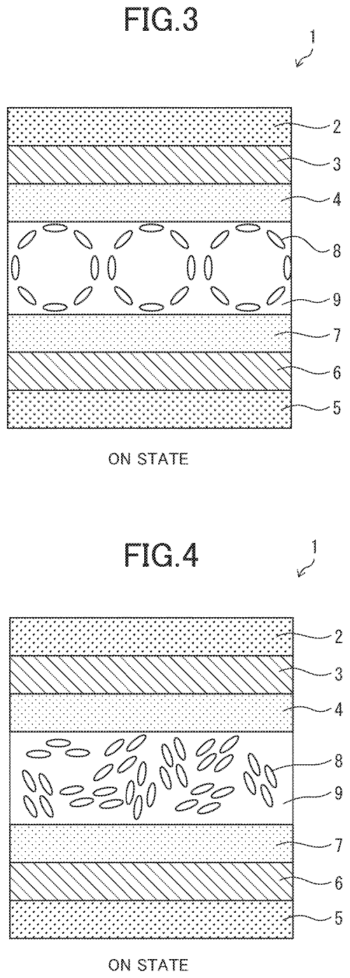

FIG. 3 is a diagram of the thermal switch 1 in the ON state, the liquid crystal molecules 8 in the liquid crystal layer 9 being in the Williams domain mode.

FIG. 3 shows the thermal switch 1 when the thermal switch 1 is on, or more specifically; when an AC voltage is applied between the first electrode 3 and the second electrode 6 in the thermal switch 1, the AC voltage having such a combination of a prescribed frequency (excitation frequency) shown in FIG. 2 and a prescribed applied voltage (effective voltage Vrms) shown in FIG. 2 that the liquid crystal molecules are in the Williams domain mode, and hence the liquid crystal molecules 8 in the liquid crystal layer 9 being in the Williams domain mode. Alternatively, although not shown, for example, a DC voltage may be applied between the first electrode 3 and the second electrode 6 while controlling the first electrode 3 and the second electrode 6, to achieve the Williams domain mode in the liquid crystal molecules 8 in the liquid crystal layer 9 in the thermal switch 1, as described earlier.

Referring to FIG. 3, when the liquid crystal molecules 8 in the liquid crystal layer 9 are in the Williams domain mode, the thermal switch 1 exhibits a sufficiently high thermal conductivity because of the convection of the liquid crystal molecules 8 as described earlier. Therefore, if the liquid crystal molecules 8 in the liquid crystal layer 9 are in the Williams domain mode when the thermal switch 1 is on, the thermal switch 1 exhibits a sufficiently high thermal conductivity on/off ratio of approximately 10 to 100.

FIG. 4 is a diagram of the thermal switch 1 in the ON state, the liquid crystal molecules 8 in the liquid crystal layer 9 being in the dynamic scattering mode.

FIG. 4 shows the thermal switch 1 when the thermal switch 1 is on, or more specifically, when an AC voltage is applied between the first electrode 3 and the second electrode 6 in the thermal switch 1, the AC voltage having such a combination of a prescribed frequency (excitation frequency) shown in FIG. 2 and a prescribed applied voltage (effective voltage Vrms) shown in FIG. 2 that the liquid crystal molecules are in the dynamic scattering mode, and hence the liquid crystal molecules 8 in the liquid crystal layer 9 being in the dynamic scattering mode. Alternatively, although not shown, for example, a DC voltage may be applied between the first electrode 3 and the second electrode 6 while controlling the first electrode 3 and the second electrode 6, to achieve the dynamic scattering mode in the liquid crystal molecules 8 in the liquid crystal layer 9 in the thermal switch 1, as described earlier.

Referring to FIG. 4, when the liquid crystal molecules 8 in the liquid crystal layer 9 are in the dynamic scattering mode, the thermal switch 1 exhibits a sufficiently high thermal conductivity because of the convection of the liquid crystal molecules 8 as described earlier. Therefore, if the liquid crystal molecules 8 in the liquid crystal layer 9 are in the dynamic scattering mode when the thermal switch 1 is on, the thermal switch 1 exhibits a sufficiently high thermal conductivity on/off ratio of approximately 10 to 100.

As detailed above, the thermal switch 1 exhibits a sufficiently high thermal conductivity on/off ratio of approximately 10 to 10 regardless of whether the liquid crystal molecules 8 in the liquid crystal layer 9 are in the Williams domain mode or in the dynamic scattering mode when the thermal switch 1 is on. The thermal switch 1 therefore needs only to be such that the liquid crystal molecules 8 in the liquid crystal layer 9 are at least either in the Williams domain mode or in the dynamic scattering mode when the thermal switch 1 is on. In other words, the liquid crystal molecules 8 in the liquid crystal layer 9 may be in the Williams domain mode, in the dynamic scattering mode, or in a mixture of the Williams domain mode and the dynamic scattering mode when the thermal switch 1 is on.

The liquid crystal molecules 8 in the liquid crystal layer 9 in the thermal switch 1 are preferably nematic liquid crystal molecules because nematic liquid crystal molecules have such a low viscosity as to likely cause electrohydrodynamic instability. The present embodiment uses N-(4-methoxybenzylidene)-4-butylaniline liquid crystal molecules, which is a nematic liquid crystal material, as the liquid crystal molecules 8. Any type of liquid crystal molecules may be used so long as the liquid crystal molecules 8 are at least either in the Williams domain mode or in the dynamic scattering mode when the thermal switch 1 is on.

The liquid crystal molecules 8 in the liquid crystal layer 9 preferably have negative dielectric anisotropy (Δε) because those liquid crystal molecules with negative dielectric anisotropy (Δε) have a low threshold voltage for achieving the Williams domain mode.

The liquid crystal layer 9 containing the liquid crystal molecules 8 preferably has a specific resistance of less than or equal to 5×10¹⁰ Ωcm.

The liquid crystal layer 9 containing the liquid crystal molecules 8 preferably contains an electrically conductive material. The electrically conductive material is preferably an organic electrolyte. Examples of the organic electrolyte include, and are not limited to, quaternary ammonium salts and tetrabutylammonium bromide.

In the present embodiment, the liquid crystal layer 9 contains a quaternary ammonium salt or tetrabutylammonium bromide (not shown) to adjust the specific resistance of the liquid crystal layer 9 containing the liquid crystal molecules 8 to less than equal to 5×10¹⁰ Ωcm.

The liquid crystal layer 9 containing the liquid crystal molecules 8 between the alignment film 4 and the alignment film 7 preferably has a thickness of greater than or equal to 5 μm and less than or equal to 1,000 μm. The liquid crystal layer 9 has a thickness of 10 μm in the present embodiment. The thickness however may vary.

The alignment film 4 and the alignment film 7 preferably horizontally align the liquid crystal molecules 8 and may be a polyimide film or a polyvinyl alcohol film that are commonly used in, for example, liquid crystal display panels. The alignment film 4 and the alignment film 7 preferably have as small a thickness as possible, preferably a thickness of less than or equal to 200 nm, and more preferably a thickness of less than or equal to 100 nm. Either one or both of the alignment film 4 and the alignment film 7 may be omitted where appropriate.

The substrate 2 and the substrate 5 are preferably made of a high thermal conductivity material such as a polyimide resin. Either one or both of the substrate 2 and the substrate 5 may contain a thermally conductive filler. Each substrate 2 and 5 preferably has a small thickness, preferably a thickness of less than or equal to 100 μm, and more preferably a thickness of less than or equal to 50 μm. Either one or both of the substrate 2 and the substrate 5 may be omitted where appropriate.

The first electrode 3 and the second electrode 6 may be made of a metal material or an electrically conductive material and are preferably made of a high-thermal-conductivity metal material or a high-thermal-conductivity electrically conductive material. Examples of such materials include various high-thermal-conductivity metal materials, high-thermal-conductivity electrically conductive materials, and high-thermal-conductivity electrically conductive metal oxides. The first electrode 3 and the second electrode 6 may he made of the same material or different materials.

The thermal switch 1 provides a sufficiently high thermal conductivity on/off ratio as described in the foregoing.

### Embodiment 2

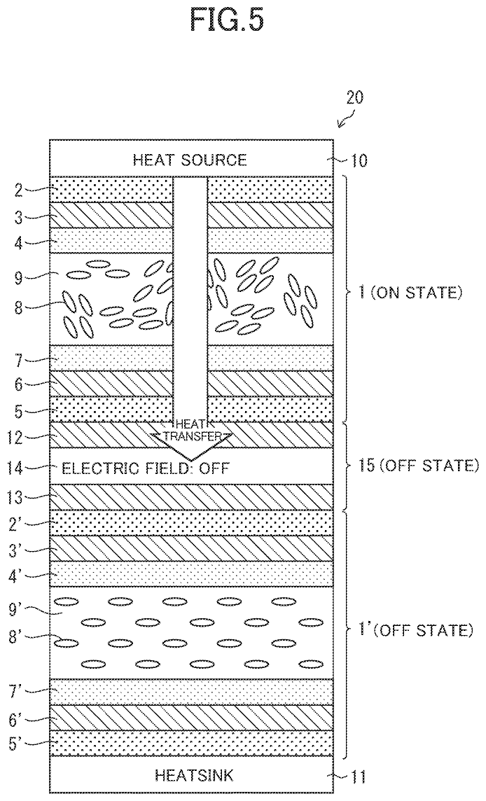

A description will be given next of Embodiment 2 of the disclosure with reference to FIGS. 5, 6, and 7. A cooling device 20 in accordance with the present embodiment differs from the thermal switch in accordance with Embodiment 1 described above in that the cooling device 20 includes two thermal switches 1 and 1′ in accordance with Embodiment 1 and a single electrocaloric device 15. Otherwise, the cooling device 20 is structured as described in Embodiment 1. For convenience of description, members of the present embodiment that have the same function as members shown in the drawings for Embodiment 1 above are indicated by the same reference numerals, and description thereof is omitted.

FIG. 5 is a diagram of the cooling device 20 in accordance with Embodiment 2 in a first state.

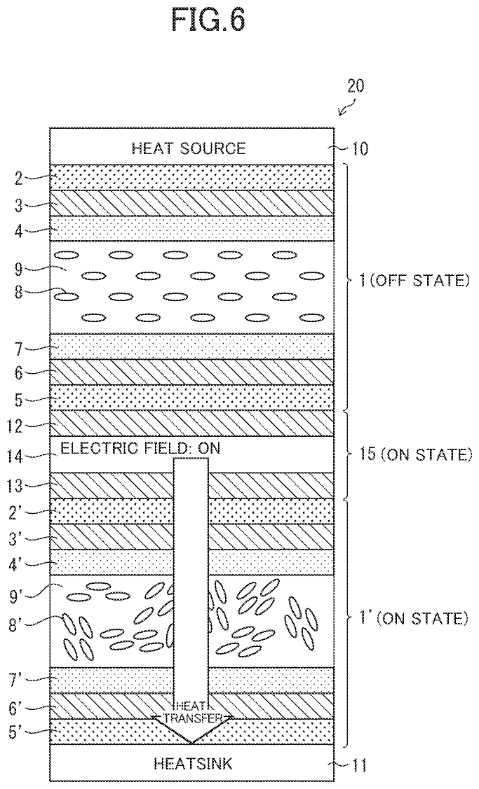

FIG. 6 is a diagram of the cooling device 20 in accordance with Embodiment 2 in a second state.

The thermal switch (first thermal switch) 1 and the thermal switch (second thermal switch) 1′ in the cooling device 20 shown in FIGS. 5 and 6 have been already described in Embodiment 1 above. Detailed description thereof is omitted in this embodiment.

The thermal switch 1 and the thermal switch 1′ may be of the same type. Alternatively, the thermal switch 1 and the thermal switch 1′ may be of different types so long as the liquid crystal molecules in the liquid crystal layer are at least either in the Williams domain mode or in the dynamic scattering mode when the thermal switches 1 and 1′ are on, in such a manner that the thermal switches 1 and 1′ have a sufficiently high thermal conductivity on/off ratio of approximately 10 to 100.

The language, “the thermal switch 1 and the thermal switch 1′ being of two different types,” used above means that the thermal switch (second thermal switch) 1′ includes a substrate 2′, a first electrode 3′, an alignment film 4′, a substrate 5′, a second electrode 6′, an alignment film 7′, liquid crystal molecules 8′, and a liquid crystal layer 9′ that are made of respective materials selected from those materials selectable for the substrate 2, the first electrode 3, the alignment film 4, the substrate 5, the second electrode 6, the alignment film 7, the liquid crystal molecules 8, and the liquid crystal layer 9 in the thermal switch (first thermal switch) 1 in accordance with Embodiment 1 above and also that at least one of these pairs of counterpart components is made of different materials between the thermal switch 1 and the thermal switch 1′.

The cooling device 20 includes the electrocaloric device 15 as shown in FIGS. 5 and 6. The electrocaloric device 15 includes a third electrode 12, a fourth electrode 13 opposite the third electrode 12, and an electrocaloric material 14 between the third electrode 12 and the fourth electrode 13.

The electrocaloric material 14 is preferably, for example, a material that exhibits a large temperature change when polarized, a material with a small specific heat or density, or a material to which a strong electric field E can be applied (see Eq. 1 below), but is not limited to these examples.

$$Δ T = - \frac{1}{C ρ} {\int }_{E 1}^{E 2} {T ( \frac{\partial P}{\partial T} )}_{E} dE \qquad Eq . 1$$

where ΔT is a temperature change caused by electrocaloric effect, C is specific heat, ρ is density, E is an electric field, T is temperature, and P is a degree of polarization.

The electrocaloric material 14 may alternatively be a relaxer ferroelectric such as poly(vinylidene fluoride-ter-trifluoroethylene-ter-chlorofluoro-ethylene) (59.4/33.4/7.2 mol %), which may be referred to as P(VDF-TrFE-CFE), or a relaxor ferroelectric-ceramic complex (see Adv. Mater, 2015, 27, 2236-2241).

As another alternative, the electrocaloric material 14 may be a liquid crystal material, a complex of a polymer material and a liquid crystal material (see, for example, a dissertation (2015) in Pennsylvania State University (https://etda.libraries.psu.edu/files/final_submissions/11060) and U.S. patent application Ser. No. 16/548,888), or a complex of a thermally conductive tiller, a polymer material, and a liquid crystal material (see U.S. patent application Ser. No. 16/548,888). The thermally conductive filler is preferably electrically insulating (see U.S. patent application Ser. No. 16/548,888).

As a further alternative, the electrocaloric material 14 may be, for example, a liquid crystal material that exhibits a large temperature change when polarized (see, for example, Adv. Mater, 2017, 1702354).

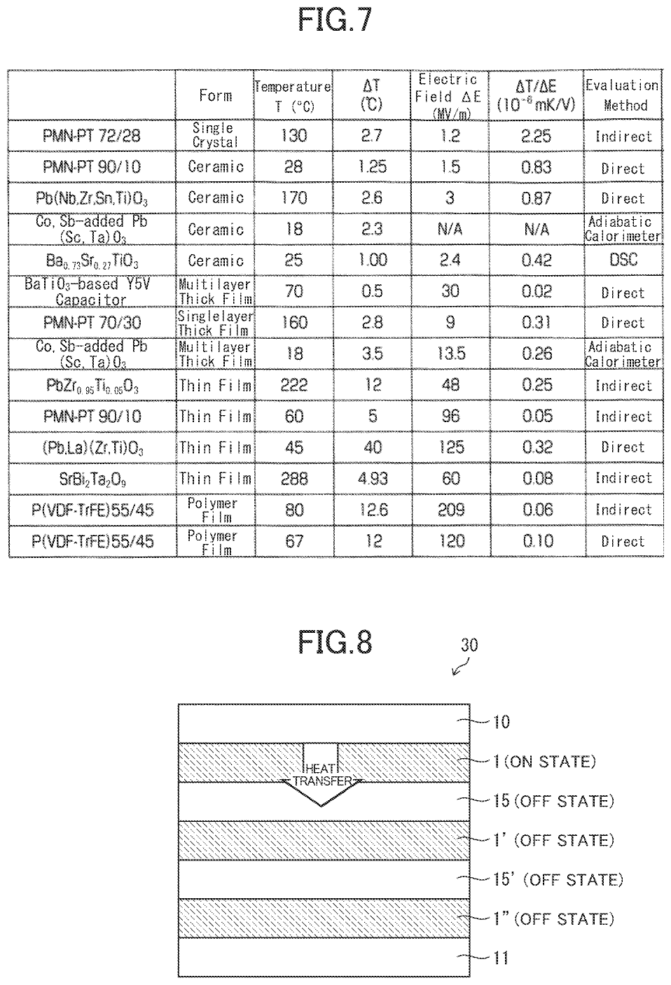

As still another alternative, the electrocaloric material 14 may be, for example, one of the materials described below with reference to FIG. 7.

FIG. 7 is a table of examples of the electrocaloric material 14 in the cooling device 20 shown in FIGS. 5 and 6.

The electrocaloric material 14 may be one of the materials listed in FIG. 7: single-crystal PMN-PT (72/28 mol %), ceramic PMN-PT (90/10 mol %), ceramic Pb(Nb,Zr,Sn,Ti)O₃, ceramic Co,Sb-added Pb(Sc,Ta)O₃, ceramic Ba_{0.73}Sr_{0.27}TiO₃, a multilayer thick film of a BaTiO₃-based Y5V capacitor, a single-layer thick film of PMN-PT (70/30 mol %), a multilayer thick film of Co,Sb-added Pb(Sc,Ta)O₃, a thin film of PbZr_{0.95}Ti_{0.05}O₃, a thin film of PMN-PT (90/10 mol %), a thin film of (Pb,La)(Zr,Ti)O₃, a thin film of SrBi₂Ta₂O₉, and a polymer film of P(VDF-TrFE) (55/45 mol %). In FIG. 7, PMN-PT denotes Pb(Mg,Nb)O₃—PbTiO₃, P(VDF-TrFE) denotes a copolymer of vinylidene fluoride and trifluoroethylene, and DSC denotes a differential scanning calorimeter.

The third electrode 12 and the fourth electrode 13 may be made of a metal material or an electrically conductive material and are preferably made of a high-thermal-conductivity metal material or a high-thermal-conductivity electrically conductive material. Examples of such materials include various high-thermal-conductivity metal materials, high-thermal-conductivity electrically conductive materials, and high-thermal-conductivity electrically conductive metal oxides. The third electrode 12 and the fourth electrode 13 may be made of the same material or different materials.

Referring to FIGS. 5 and 6, the cooling device 20 may further include a heat source 10 and a heatsink 11 in such a manner that the cooling device 20 includes the thermal switch 1 between the heat source 10 and the electrocaloric device 15 and the thermal switch 1′ between the electrocaloric device 15 and the heatsink 11.

When the cooling device 20 is in the first state as shown in FIG. 5, the electrocaloric material 14 in the electrocaloric device 15 is in the endothermic state, the thermal switch 1 is in the ON state, and the thermal switch 1′ is in the OFF state.

The electrocaloric material 14 in the electrocaloric device 15 absorbs heat when the electrocaloric device 15 is off, in other words, when the electric field E is off and generates heat when the electrocaloric device 15 is on, in other words, when the electric field E is on.

Therefore, as illustrated in FIG. 5, when the cooling device 20 is in the first state, heat is transferred from the heat source 10 to the electrocaloric material 14 by turning on the thermal switch 1, which is located close to the heat source 10, and tuning off the thermal switch 1′, which is located close to the heatsink 11, because the electrocaloric material 14 absorbs heat upon turning off the electric field E applied to the electrocaloric material 14.

When the cooling device 20 is in the second state as shown in FIG. 6, the electrocaloric material 14 in the electrocaloric device 15 is in the exothermic state, the thermal switch 1 is in the OFF state, and the thermal switch 1′ is in the ON state.

The electrocaloric material 14 in the electrocaloric device 15 absorbs heat when the electrocaloric device 15 is off, in other words, when the electric field E is off and generates heat when the electrocaloric device 15 is on, in other words, when the electric field E is on.

Therefore, as illustrated in FIG. 6, when the cooling device 20 is in the second state, heat is transferred from the electrocaloric material 14 to the heatsink 11 by turning off the thermal switch 1, which is located close to the heat source 10, and turning on the thermal switch 1′, which is located close to the heatsink 11, because the electrocaloric material 14 generates heat upon turning on the electric field E applied to the electrocaloric material 14.

The cooling device 20 cools the heat source 10 by repeatedly toggling between the first state shown in FIG. 5 and the second state shown in FIG. 6.

The cooling device 20 includes the thermal switches 1 and 1′ with a sufficiently high thermal conductivity on/off ratio as described in the foregoing. The cooling device 20 therefore provides high cooling efficiency and high cooling capability.

The present embodiment has described, as an example, the cooling device 20 including the two thermal switches 1 and 1′ and the single electrocaloric device 15. Alternatively, the cooling device may include a single thermal switch 1 and a single electrocaloric device 15. When the cooling device includes a single thermal switch 1 and a single electrocaloric device 15, the thermal switch 1 is provided close to the heat source 10, and the electrocaloric device 15 is provided close to the heatsink 11, both between the heat source 10 and the heatsink 11. In this structure, heat is transferred from the heat. source 10 to the electrocaloric material 14 in the first state by turning on the thermal switch 1, which is located close to the heat source 10, because the electrocaloric material 14 absorbs heat upon turning off the electric field E applied to the electrocaloric material 14, whereas heat is transferred from the electrocaloric material 14 to the heatsink 11 in the second state by turning off the thermal switch 1, which is located close to the heat source 10, because the electrocaloric material 14 generates heat upon turning on the electric field E applied to the electrocaloric material 14. The cooling device hence cools the heat source 10 by repeatedly toggling between the first state and the second state.

The cooling device may include a plurality of thermal switches and a plurality of electrocaloric devices, which is detailed next in Embodiment 3.

### Embodiment 3

A description will be given next of Embodiment 3 of the disclosure with reference to FIGS. 8, 9, and 10. A cooling device 30 in accordance with the present embodiment differs from Embodiment 2 above in that the cooling device 30 includes a plurality of thermal switches in accordance with Embodiment 1 (three thermal switches 1, 1′, and 1″ in the present embodiment) and a plurality of electrocaloric devices (two electrocaloric devices 15 and 15′ in the present embodiment). Otherwise, the cooling device 30 is structured as described in Embodiments 1 and 2. For convenience of description, members of the present embodiment that have the same function as members shown in the drawings for Embodiments 1 and 2 above are indicated by the same reference numerals, and description thereof is omitted.

FIG. 8 is a diagram of the cooling device 30 in accordance with Embodiment 3 in a first state.

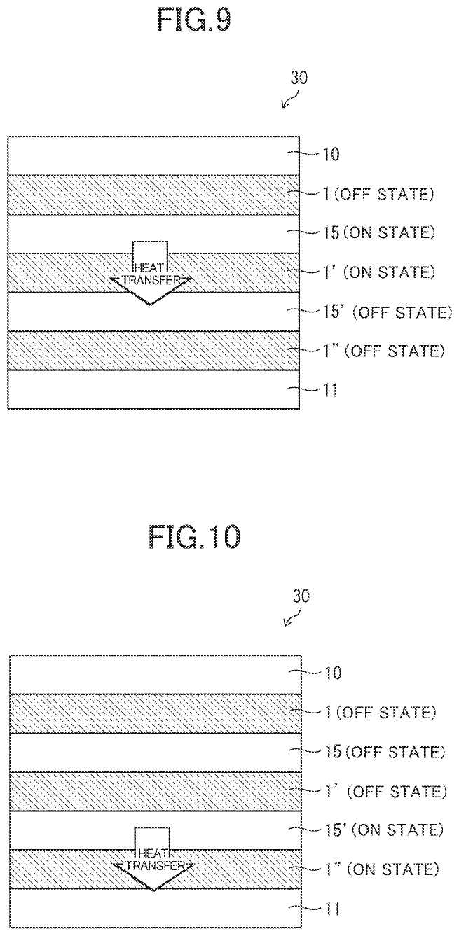

FIG. 9 is a diagram of the cooling device 30 in accordance with Embodiment 3 in a second state.

FIG. 10 is a diagram of the cooling device 30 in accordance with Embodiment 3 in a third state.

The thermal switch (first thermal switch) 1, the thermal switch (second thermal switch) 1′, and the thermal switch (third thermal switch) 1″ in the cooling device 30 shown in FIGS. 8, 9, and 10 have been already described in Embodiment 1 above. Detailed description thereof is omitted in this embodiment.

The thermal switch 1, the thermal switch 1′, and the thermal switch 1″ may be of the same type. Alternatively, the thermal switch 1, the thermal switch 1′, and the thermal switch 1″ may be of two or three different types so long as the liquid crystal molecules in the liquid crystal layer are at least either in the Williams domain mode or in the dynamic scattering mode when the thermal switches 1, 1′, and 1″ are on, in such a manner that the thermal switches 1, 1′, and 1″ have a sufficiently high thermal conductivity on/off ratio of approximately 10 to 100.

The language, “the thermal switch 1, the thermal switch 1′, and the thermal switch 1″ being of three different types,” used above means that the thermal switch 1 and the thermal switch 1′ are of two different types as described in Embodiment 2 and further that the thermal switch 1″ is a different type of thermal switch from the thermal switch 1 and the thermal switch 1′.

Referring to FIGS. 8, 9, and 10, the cooling device 30 includes the electrocaloric device (first electrocaloric device) 15 and the electrocaloric device (second electrocaloric device) 15′.

The electrocaloric device 15 and the electrocaloric device 15′ may be of the same type. Alternatively, the electrocaloric device 15 and the electrocaloric device 15′ may be of two different types so long as the electrocaloric material in the electrocaloric device absorbs heat when the electrocaloric device is off, in other words, when the electric field E is off and generates heat when the electrocaloric device is on, in other words, when the electric field E is on.

The language, “the electrocaloric device 15 and the electrocaloric device 15′ being of two different types,” used above means that the electrocaloric device (second electrocaloric device) 15′ includes a third electrode, a fourth electrode, and an electrocaloric material that are made of respective materials selected from those materials selectable for the third electrode 12, the fourth electrode 13, and the electrocaloric material 14 in the electrocaloric device (first electrocaloric device) 15 in accordance with Embodiment 2 above and also that at least one of these pairs of counterpart components is made of different materials between the electrocaloric device 15 and the electrocaloric device 15′.

Referring to FIGS. 8, 9, and 10, the cooling device 30 may further include a heat source 10 and a heatsink 11 in such a manner that the cooling device 30 includes the thermal switch 1 between the heat source 10 and the first electrocaloric: device 15, the thermal switch 1′ between the electrocaloric device 15 and the electrocaloric device 15′, and the thermal switch 1″ between the electrocaloric device 15′ and the heatsink 11.

When the cooling device 30 is in the first state as shown in FIG. 8, the electrocaloric material in the electrocaloric device 15 is in the endothermic state, the thermal switch 1 is in the ON state, and the thermal switch 1′ is in the OFF state, The thermal switch 1″, which is located close to the heatsink 11, may be either in the ON state or in the OFF state, but preferably in the OFF state, for example, in view of power consumption.

The electrocaloric material in the electrocaloric device 15 absorbs heat when the electrocaloric device 15 is off, in other words, when the electric field E is off and generates heat when the electrocaloric device 15 is on, in other words, when the electric field E is on.

Therefore, as illustrated in FIG. 8, when the cooling device 30 is in the first state, heat is transferred from the heat source 10 to the electrocaloric material in the electrocaloric device 15 by turning on the thermal switch 1, which is located close to the heat source 10, and turning off the thermal switch 1′, which is located close to the heatsink 11, because the electrocaloric material in the electrocaloric device 15 absorbs heat upon turning off the electric field E applied to the electrocaloric material in the electrocaloric device 15.

When the cooling device 30 is in the second state as shown in FIG. 9, the electrocaloric material in the electrocaloric device 15 is in the exothermic state, the thermal switch 1 is in the OFF state, the thermal switch 1′ is in the ON state, the electrocaloric material in the electrocaloric device 15′ is in the endothermic state, and the thermal switch 1″ is in the OFF state.

The electrocaloric material in the electrocaloric device 15′ absorbs heat when the electrocaloric device 15′ is in off, in other words, when the electric field E is off and generates heat when the electrocaloric device 15′ is on, in other words, when the electric field E is on.

Therefore, as illustrated in FIG. 9, when the cooling device 30 is in the second state, heat is transferred from the electrocaloric material in the electrocaloric device 15 to the electrocaloric material in the electrocaloric device 15′ by turning off the thermal switch 1, which is located close to the heat source 10, turning on the thermal switch 1′ between the electrocaloric device 15 and the electrocaloric device 15′, turning off the electric field E applied to the electrocaloric material in the electrocaloric device 15′, so that the electrocaloric material in the electrocaloric device 15′ is in the endothermic state, and turning off the thermal switch 1″, which is located close to the heatsink 11, because the electrocaloric material in the electrocaloric device 15 generates heat upon turning on the electric field E applied to the electrocaloric material in the electrocaloric device 15.

When the cooling device 30 is in the third state as shown in FIG. 10, the electrocaloric material in the electrocaloric device 15′ is in the exothermic state, the thermal switch 1′ is in the OFF state, and the thermal switch 1″ is in the ON state. The thermal switch 1, which is located close to the heat source 10, may be either in the ON state or in the OFF state, but preferably in the OFF state, for example, in view of power consumption.

Therefore, as illustrated in FIG. 10, when the cooling device 30 is in the third state, heat is transferred from the electrocaloric material in the electrocaloric device 15′ to the heatsink 11 by turning off the thermal switch between the electrocaloric device 15 and the electrocaloric device 15′ and turning on the thermal switch 1″, which is located close to the heatsink 11, because the electrocaloric material in the electrocaloric device 15′ generates heat upon turning off the electric field E applied to the electrocaloric material in the electrocaloric device 15′.

The cooling device 30 cools the heat source 10 by repeatedly toggling between the first state shown in FIG. 8, the second state shown in FIG. 9, and the third state shown in FIG. 10 in this sequence.

The cooling device 30 includes the thermal switches 1, 1′, and 1″ with a sufficiently high thermal conductivity on/off ratio as described in the foregoing. The cooling device 30 therefore provides high cooling efficiency and high cooling capability.

The present embodiment has described, as an example, the cooling device 30 including the three thermal switches 1, 1′, and 1″ and the two electrocaloric devices 15 and 15′. This is however not the only possible implementation of the disclosure, Alternatively, the cooling device may include four or more thermal switches and three or more electrocaloric devices.

### Embodiment 4

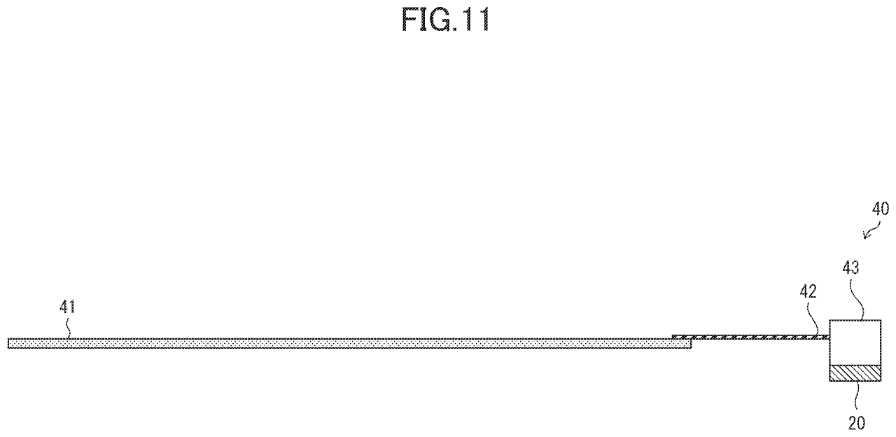

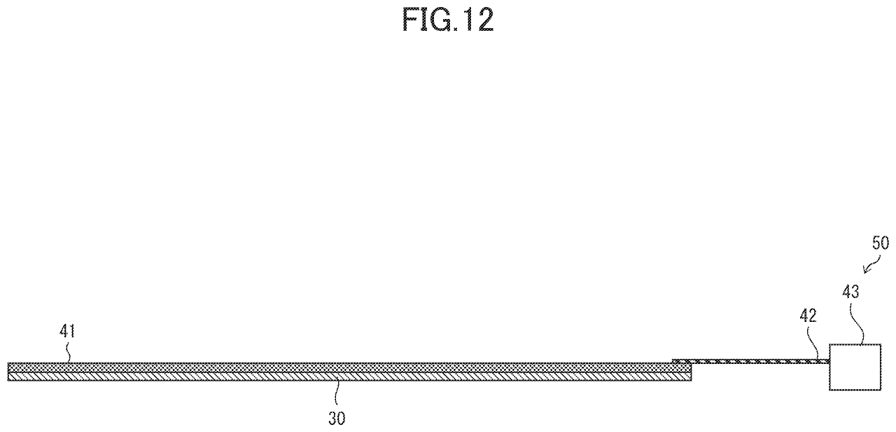

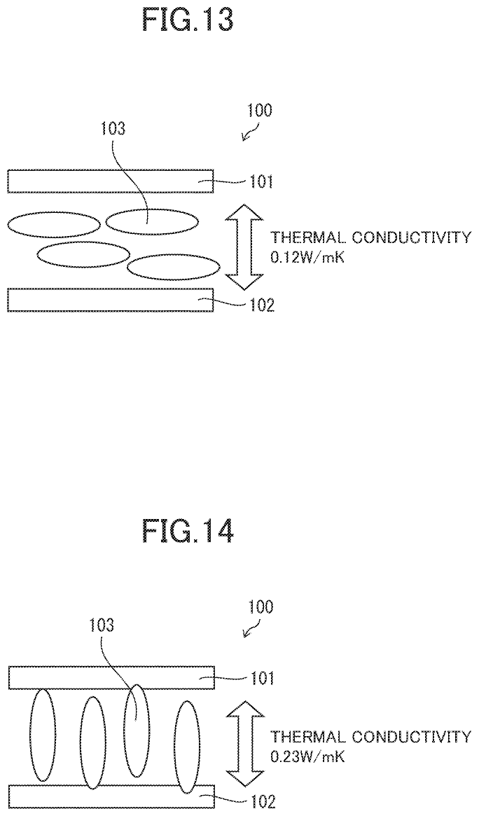

A description will be given next of Embodiment 4 of the disclosure with reference to FIGS. 11 and 12. Display devices 40 and 50 in accordance with the present embodiment differ from Embodiments 1 to 3 above in that the display devices 40 and 50 include cooling devices 20 and 30 in accordance with Embodiments 2 and 3 above respectively. Otherwise, the display devices 40 and 50 are structured as described in Embodiments 1 to 3. For convenience of description, members of the present embodiment that have the same function as members shown in the drawings for Embodiments 1 to 3 above are indicated by the same reference numerals, and description thereof is omitted.

FIG. 11 is a schematic diagram of a structure of the display device 40 including the cooling device 20 in accordance with Embodiment 2 shown in FIGS. 5 and 6.

The display device 40 includes a display panel 41, a control circuit 43, wiring 42, and the cooling device 20. The wiring 42 electrically connects the wires on the display panel 41 to the terminals of the control circuit 43. Hence, the heat-generating control circuit 43 is a heat source 10 for the cooling device 20. There may be provided, for example, a heat dissipation plate as a heatsink 11 for the cooling device 20. There may be provided electrode-controlling circuitry (not shown) for the cooling device 20 either as part of the control circuit 43 or separately from the control circuit 43.

FIG. 12 is a schematic diagram of a structure of the display device 50 including the cooling device 30 in accordance with Embodiment 3 shown in FIGS. 8, 9, and 10.

The display device 50 includes a display panel 41, a control circuit 43, wiring 42, and the cooling device 30. The wiring 42 electrically connects the wires on the display panel 41 to the terminals of the control circuit 43. Hence, the heat-generating display panel 41 is a heat source 10 for the cooling device 30. There may be provided, for example, a heat dissipation plate as a heatsink 11 for the cooling device 30. There may be provided electrode-controlling circuitry (not shown) for the cooling device 30 either as part of the control circuit 43 or separately from the control circuit 43.

The display device 40 shown in FIG. 11 includes the cooling device 20 as the only cooling device for cooling the control circuit 43, and the display device 50 shown in FIG. 12 includes the cooling device 30 as the only cooling device for cooling the display panel 41. Alternatively, the cooling device 30 may be used to cool the control circuit 43, and the cooling device 20 to cool the display panel 41. As another alternative, the display device may include two separate cooling devices, one for cooling the control circuit and the other for cooling the display panel. The display device, as a further alternative, may include a single, integrated cooling device for cooling both the control circuit and the display panel.

Display devices tend to age quickly at high temperature. The display devices 40 and 50 in accordance with the present embodiment, the temperature of which is restrained from rising at high temperature, age more slowly. Some display device components sacrifice, for example, optical properties thereof for the sake of operability at high temperature. The components of the display devices 40 and 50 in accordance with the present embodiment are less likely to be degraded when used at high temperature and may therefore be selected from a broader range of candidate components for better optical and other properties.

### Additional Remarks

The disclosure is not limited to the description of the embodiments above and may be altered within the scope of the claims. Embodiments based on a proper combination of technical means disclosed in different embodiments are encompassed in the technical scope of the disclosure. Furthermore, new technological features can be created by combining different technological means disclosed in the embodiments.

### INDUSTRIAL APPLICABILITY

The present disclosure is applicable to thermal switches, cooling devices, and display devices.

What is claimed is:

1. A thermal switch comprising:
a first electrode;
a second electrode opposite the first electrode; and
a liquid crystal layer between the first electrode and the second electrode, the liquid crystal layer containing liquid crystal molecules that are at least either in Williams domain mode or in dynamic scattering mode when a voltage is applied between the first electrode and the second electrode.

2. The thermal switch according to claim 1, wherein the liquid crystal molecules are nematic liquid crystal molecules.

3. The thermal switch according to claim 1 wherein the liquid crystal molecules are homogeneously oriented when no voltage is applied between the first electrode and the second electrode.

4. The thermal switch according to claim 1, wherein the liquid crystal molecules have negative dielectric anisotropy.

5. The thermal switch according to claim 1, wherein the liquid crystal layer has a specific resistance of less than or equal to 5×10¹⁰ Ωcm.

6. The thermal switch according to claim 1, wherein an AC voltage is applied between the first electrode and the second electrode.

7. The thermal switch according to claim 1, wherein the liquid crystal layer contains an electrically conductive material.

8. The thermal switch according to claim 7, wherein the electrically conductive material is an organic electrolyte.

9. The thermal switch according to claim 8, wherein the organic electrolyte is either a quaternary ammonium salt or tetrabutylammonium bromide.

10. The thermal switch according to claim 1, wherein the liquid crystal layer has a thickness of greater than or equal to 5 μm and less than or equal to 1,000 μm.

11. A cooling device comprising:
at least one electrocaloric device including:
a third electrode;
a fourth electrode opposite the third electrode; and
an electrocaloric material between the third electrode and the fourth electrode; and
at least one thermal switch according to claim 1.

12. The cooling device according to claim 11, further comprising a heat source and a heatsink, wherein the at least one thermal switch comprises a first thermal switch between the heat source and the at least one electrocaloric device and a second thermal switch between the at least one electrocaloric device and the heatsink.

13. The cooling device according to claim 12 that repeatedly toggles between a first state where the electrocaloric material in the at least one electrocaloric device is in an endothermic state, the first thermal switch is in an ON state, and the second thermal switch is in an OFF state and a second state where the electrocaloric material in the at least one electrocaloric device is in an exothermic state, the first thermal switch is in an OFF state, and the second thermal switch is in an ON state.

14. The cooling device according to claim 11, further comprising a heat source and a heatsink, wherein
the at least one thermal switch comprises a first thermal switch, a second thermal switch, and a third thermal switch,
the at least one electrocaloric device comprises a first electrocaloric device and a second electrocaloric device,
the first thermal switch is disposed between the heat source and the first electrocaloric device,
the second thermal switch is disposed between the first electrocaloric device and the second electrocaloric device, and
the third thermal switch is disposed between the second electrocaloric device and the heatsink.

15. The cooling device according to claim 14 that repeatedly toggles between a first state where the electrocaloric material in the first electrocaloric device is in an endothermic state, the first thermal switch is in an ON state, and the second thermal switch is in an OFF state, a second state where the electrocaloric material in the first electrocaloric device is in an exothermic state, the first thermal switch is in an OFF state, the second thermal switch is in an ON state, the third thermal switch is in an OFF state, and the electrocaloric material in the second electrocaloric device is in an endothermic state, and a third state where the electrocaloric material in the second electrocaloric device is in an exothermic state, the second thermal switch is in an OFF state, and the third thermal switch is in an ON state in a sequence of the first state, the second state, and the third state.

16. A display device comprising:
a cooling device according to claim 11; and a display panel.
